(19) United States
(12) Patent Application Publication
(10) Pub. No.: US 2010/0142118 A1
(43) Pub. Date: Jun. 10, 2010

(54) COPPER-CLAD LAMINATE WITH CAPACITOR, PRINTED CIRCUIT BOARD HAVING THE SAME, AND SEMICONDUCTOR PACKAGE HAVING THE PRINTED CIRCUIT BOARD

(76) Inventor: Woong Sun LEE, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/492,835

(22) Filed: Jun. 26, 2009

(30) Foreign Application Priority Data
Dec. 10, 2008 (KR) 10-2008-0125457

(51) Int. Cl. H05K 1/18; H01G 4/224

(52) U.S. Cl. 361/301.3; 174/260; 361/782

(57) ABSTRACT

A copper-clad laminate with a capacitor, a printed circuit board having the same and a semiconductor package having the printed circuit board are presented. The copper-clad laminate with the capacitor includes a first and second conductive layers, a film body, and thickness uniformity improving members. The first and second conductive layers are aligned to be substantially in parallel to each other and thus oppose each other. The film body is interposed between the first and the second conductive layer. The thickness uniformity improving members are also interposed between the first and second conductive layers and are inserted within the film body. The thickness uniformity improving members have one end connected to the first conductive layer and have the opposing ends connected to the second conductive layer.

### CROSS-REFERENCE TO RELATED APPLICATIONS

The present application claims priority to Korean patent application number 10-2008-0125457 filed on Dec. 10, 2008, which is incorporated herein by reference in its entirety.

### BACKGROUND OF THE INVENTION

The present invention relates to a semiconductor package, and more particularly, to a copper-clad laminate with a capacitor in which thickness uniformity improving members are disposed, a printed circuit board using the same, and a semiconductor package having the printed circuit board.

Recently, the electronic industry tends to adopt mounting technology using a printed circuit board capable of permitting high density and high precision mounting of parts so as to accomplish miniaturization and high performance of electronic products. In particular, with the development of a CSP (chip size package) such as a BGA (ball grid array) package and a TCP (tape carrier package), interest for a high density printed circuit board capable of mounting an increased number of parts, that is, semiconductor packages, increases gradually.

Therefore, in order to realize electronic products which are light, slim, compact and miniaturized, not only techniques for finely forming parts are required, but also a printed circuit board for enabling high density mounting of parts should also be provided. The printed circuit board is structured by forming circuit patterns on an insulation layer using a conductive material such a copper, and represents a board immediately before mounting electronic parts to construct a module.

Meanwhile, recently, in order to accomplish making light weight, slimness, compactness, miniaturization and high performance of electronic products, interest in passive devices has also gradually increased. However, since most currently used passive devices are mounted to the surface of a printed circuit board as discrete parts, they occupy a substantial area on the printed circuit board. Also, because the distance between the passive devices is substantial, inductance components can be markedly influenced when exposed to high frequencies, which serves as a factor deteriorating electrical performance. Further, as the number of soldering connections increases, the reliability of a product tends to be degraded.

In order to overcome these problems, an embedded passive device has been disclosed in the art. The embedded passive device is manufactured in a manner such that a passive device such as a capacitor is directly integrated in a substrate having a multi-layered structure.

In the case of such an embedded passive device, since the area occupied by the general passive device can be reduced, then a chip mounting density can be increased. Also since a connection length between passive devices is shortened with these embedded passive devices, then unwanted inductance components can be diminished. As a result of using embedded passive devices the resultant electrical performances tend to be improved.

Among passive devices, capacitors roughly correspond to well over 40% of all of the entire passive devices. Capacitors perform important roles in an electronic circuit such as in the case of a decoupling capacitor and a bypass capacitor. For this reason, research has actively been pursued in hopes of developing high quality capacitors.

While not shown and described in detail, in a printed circuit board adopting the conventional embedded passive device, because a passive device such as a capacitor is directly integrated in the printed circuit board having a multi-layered structure, a drawback is caused in that the overall thickness of the printed circuit board increases.

Moreover, in the printed circuit board adopting the conventional embedded passive device, since various additional processes for directly integrating the passive device in the printed circuit board are required, a manufacturing procedure is involved, and as a result the manufacturing cost increases.

### BRIEF SUMMARY OF THE INVENTION

Embodiments of the present invention are directed to a copper-clad laminate which can protect against or prevent the overall thickness of a printed circuit board from increasing upon integrating a capacitor in the printed circuit board.

Also, embodiments of the present invention are directed to a printed circuit board which is constituted using a copper-clad laminate with a capacitor.

Further, embodiments of the present invention are directed to a semiconductor package which has a printed circuit board having a capacitor integrated therein in such a way as to prevent or at least protect against a thickness from increasing.

In one embodiment of the present invention, a copper-clad laminate with a capacitor comprises a first and second conductive layer opposing each other; a film body interposed between the first and second conductive layer; and thickness uniformity improving members interposed between the first and second conductive layer and inserted within the film body, the thickness uniformity improving members having ends which are connected to the first conductive layer and having opposing ends connected to the second conductive layer such that the thickness uniformity improving members provide a substantial uniform thickness of the film body between the first and second conductive layers.

The first and second conductive layers are formed of any electrically conductive material such as those selected from the group consisting of Cu, Al, Ni, Fe, Au, Ag and alloys thereof.

The film body includes a plurality of dielectric elements and a binder that envelopes the dielectric elements.

The dielectric elements can have a dielectric constant in which it is preferable that the dielectric constant is within a range of 3˜1000.

The dielectric elements can be composed of any dielectric material such as those selected from the group consisting of silica, barium titanate (BT), strontium titanate (ST), barium strontium titanate (BST), titanate (TiO₃), lead zirconium titanate (PZT), lead lanthanum titanate (PLT), lead lanthanum zirconate titanate (PLZT), bismuth titanate (BIT), potassium tantalite (KTA), lead scandium tantalite (PST), lead niobate (PN), lead zinc niobate (PZN), potassium niobate (KN), lead magnesium niobate (PMNO), strontium bismuth tantalate (SBT) and strontium bismuth tantalate niobate (SBTN), and combinations thereof.

The binder contains epoxy resin.

The thickness uniformity improving members are formed of an insulation substance.

The insulation substance comprises any one of polypropylene, polyethylene, epoxy and nylon.

The thickness uniformity improving members are formed in the shape of a column or a ball.

The column of the thickness uniformity improving members can have be a cylindrical column or a polygonal column. The ball of the thickness uniformity improving members can be an irregular shaped ball, an elliptically shaped ball or a spherical ball. The cylindrical column preferably has a diameter of about 1.5˜2.5 μm and a height of about 9˜11 μm.

The distribution of the thickness uniformity improving members may be any ordered or random pattern as well as distances between adjacent thickness uniformity improving members may be any distance. One preferred embodiment is that adjacent thickness uniformity improving members are preferably evenly distributed in the film body at an interval of about 48˜52 mm.

In another aspect of the present invention, a printed circuit board comprises a copper-clad laminate with a capacitor, including a first conductive layer, a second conductive layer facing away from the first conductive layer, a film body interposed between the first conductive layer and the second conductive layer, and thickness uniformity improving members inserted in the film body and having one ends which are connected to the first conductive layer and the other ends which face away from the one ends and are connected to the second conductive layer; insulation layers formed on upper and lower surfaces, respectively, of the copper-clad laminate which face away from each other; and wiring lines formed on the insulation layers and connected to the first conductive layer and second conductive layer.

The insulation layers are formed to have a single-layered or multi-layered structure.

The wiring lines are formed at least on one of upper and lower surfaces of the insulation layers.

The printed circuit board may further comprise solder resists formed on the insulation layers including the wiring lines so that the solder resists expose portions of the wiring lines.

In still another embodiment of the present invention, a semiconductor package comprises a printed circuit board including a copper-clad laminate with a capacitor, comprising a first conductive layer, a second conductive layer facing away from the first conductive layer, a film body interposed between the first conductive layer and the second conductive layer, and thickness uniformity improving members inserted in the film body and having one ends which are connected to the first conductive layer and the other ends which face away from the one ends and are connected to the second conductive layer, insulation layers formed on upper and lower surfaces, respectively, of the copper-clad laminate which face away from each other, and wiring lines formed on the insulation layers and connected to the first conductive layer and second conductive layer; a semiconductor chip attached to one surface of the printed circuit board and having bonding pads; and connection members electrically connecting the bonding pads of the semiconductor chip and the wiring lines of the printed circuit board.

The semiconductor package further comprises an encapsulant covering the one surface of the printed circuit board including the semiconductor chip and the connection members; and external connection members attached to the other surface of the printed circuit board.

The semiconductor chip is placed on the one surface of the printed circuit board in a face-up type.

The semiconductor chip is placed on the one surface of the printed circuit board in a face-down type, and the printed circuit board has a cavity.

### BRIEF DESCRIPTION OF THE DRAWINGS

FIG. 1 is a sectional view illustrating a copper-clad laminate with a capacitor in accordance with a first embodiment of the present invention.

FIG. 2 is a sectional view illustrating a printed circuit board in accordance with a second embodiment of the present invention.

FIG. 3 is a sectional view illustrating a semiconductor package in accordance with a third embodiment of the present invention.

FIG. 4 is a sectional view illustrating a semiconductor package in accordance with a fourth embodiment of the present invention.

FIG. 5 is a sectional view illustrating a semiconductor package in accordance with a fifth embodiment of the present invention.

### DESCRIPTION OF SPECIFIC EMBODIMENTS

Hereafter, specific embodiments of the present invention will be described in detail with reference to the accompanying drawings.

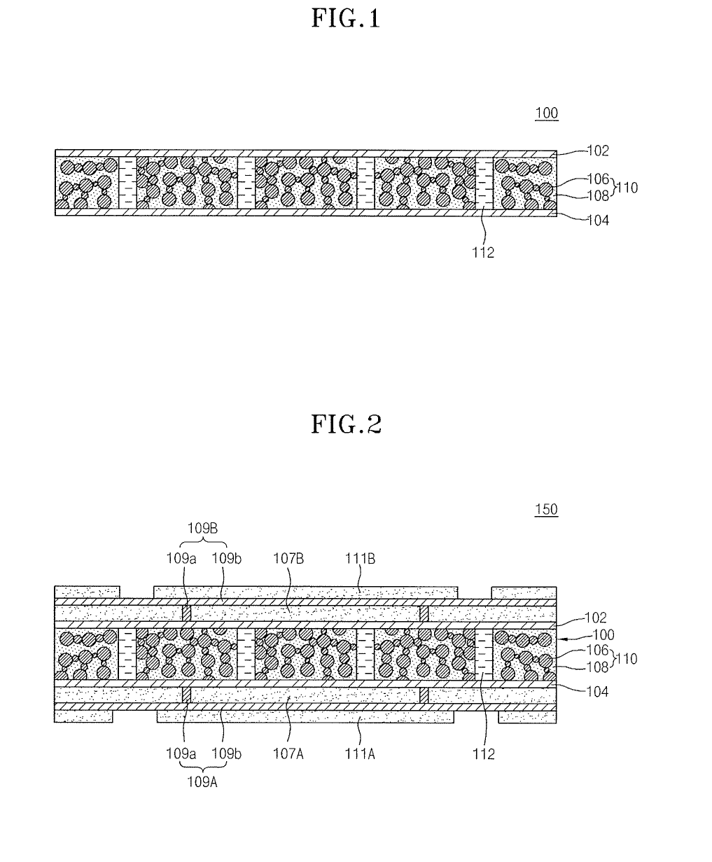

FIG. 1 is a sectional view illustrating a copper-clad laminate with a capacitor in accordance with a first embodiment of the present invention. It is understood herein that the drawings are not necessarily to scale and in some instances proportions may have been exaggerated in order to more clearly depict certain features of the invention.

Referring to FIG. 1, a copper-clad laminate 100 with a capacitor in accordance with a first embodiment of the present invention includes a first conductive layer 102 and a second conductive layer 104 which face away from each other, a film body 110 which is interposed between the first conductive layer 102 and the second conductive layer 104, and thickness uniformity improving members 112 which are inserted in the film body 110.

The first conductive layer 102 and the second conductive layer 104 are placed to be separated from each other by a predetermined distance. The first conductive layer 102 and the second conductive layer 104 are formed of any one of, for example, Cu, Al, Ni, Fe, Au, Ag, and alloys thereof.

The film body 110 includes a plurality of dielectric elements 106 and a binder 108 which envelops the plurality of dielectric elements 106. The dielectric elements 106 preferable have a dielectric constant within a range of 3˜1000. Accordingly, the dielectric elements 106 can be composed of any dielectric material such as those selected from the group consisting of silica, barium titanate (BT), strontium titanate (ST), barium strontium titanate (BST), titanate (TiO₃), lead zirconium titanate (PZT), lead lanthanum titanate (PLT), lead lanthanum zirconate titanate (PLZT) bismuth titanate (BIT), potassium tantalite (KTA), lead scandium tantalite (PST), lead niobate (PN), lead zinc niobate (PZN), potassium niobate (KN), lead magnesium niobate (PMNO), strontium bismuth tantalate (SBT) and strontium bismuth tantalate niobate (SBTN), and combinations thereof. The binder 108 preferably contains epoxy resin.

The thickness uniformity improving members 112 have one ends which are connected to the first conductive layer 102 and the other ends which face away from the one ends connected to the first conductive layer 102 and are connected to the second conductive layer 104. The thickness uniformity improving members 112 are inserted in the film body 110 and function to constantly maintain the thickness of the film body 110, that is, improve the thickness uniformity of the film body 110.

The thickness uniformity improving members 112 are formed of an insulation substance. For example, the thickness uniformity improving members 112 are formed of any one of, for example, polypropylene, polyethylene, epoxy and nylon. Also, the thickness uniformity improving members 112 are formed in the shape of any one of a column such as a cylindrical column and a polygonal column and a ball. For example, the thickness uniformity improving members 112 can be formed in the shape of a circular column of which upper surfaces and lower surfaces facing away from the upper surfaces, contacting the first conductive layer 102 and the second conductive layer 104, are flat and which has a diameter and a height of about 1.5˜2.5 μm and about 9˜11 μm, preferably, about 2 μm and about 10 μm, respectively. Adjacent thickness uniformity improving members 112 are preferably distributed in the film body 110 at an interval of 48˜52 mm, preferably, 50 mm.

The thickness uniformity improving members 112 can have any shape so long as they are placed in the film body 110 and improve the thickness uniformity of the film body 110.

FIG. 2 is a sectional view illustrating a printed circuit board using the above-described copper-clad laminate in accordance with a second embodiment of the present invention.

Referring now to FIG. 2, a printed circuit board 150 in accordance with a second embodiment of the present invention includes a copper-clad laminate 100 with a capacitor, insulation layers 107A and 107B, and wiring lines 109A and 109B.

The copper-clad laminate 100 with a capacitor has a construction in which a film body 110 is interposed between a first conductive layer 102 and a second conductive layer 104 facing away from each other and thickness uniformity improving members 112 for uniformly maintaining the thickness of the film body 110 are inserted in the film body 110.

The first conductive layer 102 and the second conductive layer 104 are formed of any one of, for example, Cu, Al, Ni, Fe, Au, Ag and alloys thereof. The film body 110 includes a plurality of dielectric elements 106 and a binder 108 which captures the plurality of dielectric elements 106. The dielectric elements 106 contain those selected from the group consisting of silica, barium titanate (BT), strontium titanate (ST), barium strontium titanate (BST), titanate (TiO₃), lead zirconium titanate (PZT), lead lanthanum titanate (PLT), lead lanthanum zirconate titanate (PLZT), bismuth titanate (BIT), potassium tantalite (KTA), lead scandium tantalite (PST), lead niobate (PN), lead zinc niobate (PZN), potassium niobate (KN), lead magnesium niobate (PMNO), strontium bismuth tantalate (SBT) and strontium bismuth tantalate niobate (SBTN), and combinations thereof, and the binder 108 contains epoxy resin. The dielectric elements 106 can be formed of any substance so long as the substance has a dielectric constant of between about 3˜1000.

The thickness uniformity improving members 112 are formed of an insulation substance such as polypropylene, polyethylene, epoxy and nylon. The thickness uniformity improving members 112 are formed in the shape of any one of, for example, a column such as a cylindrical column and a polygonal column and a ball. In particular, the thickness uniformity improving members 112 can be formed in any shape so long as they can improve the thickness uniformity of the film body 110. For example, the thickness uniformity improving members 112 can be formed in the shape of a cylindrical column which has a diameter and a height of about 1.5˜2.5 μm and about 9˜11 μm, preferably, about 2 μm and about 10 μm, respectively. The thickness uniformity improving members 112 are inserted in the film body 110 at an interval of about 48˜52 mm, preferably, about 50 mm.

The insulation layers 107A and 107B are respectively formed on the lower and upper surfaces of the copper-clad laminate 100 which face away from each other. These insulation layers 107A and 107B can be formed to have a single-layered or multi-layered structure depending upon the desired thickness of the printed circuit board 150.

The wiring lines 109A and 109B are placed on the insulation layers 107A and 107B placed on the lower and upper surfaces of the copper-clad laminate 100 facing away from each other and are electrically connected with the second conductive layer 104 and the first conductive layer 102, respectively. These wiring lines 109A and 109B include via wiring lines 109a which are formed in the insulation layers 107A and 107B and circuit wiring lines 109b which are formed on the insulation layers 107A and 107B.

The wiring lines 109A and 109B can be formed on both the upper and lower surfaces of the insulation layers 107A and 107B or selectively on either one of the upper and lower surfaces of the insulation layers 107A and 107B, depending upon the type of a package and the design of the printed circuit board 150.

The printed circuit board 150 in accordance with the second embodiment of the present invention further includes solder resists 111A and 111B which are formed on the insulation layers 107A and 107B including the wiring lines 109A and 109B in such a way as to expose portions of the wiring lines 109A and 109B.

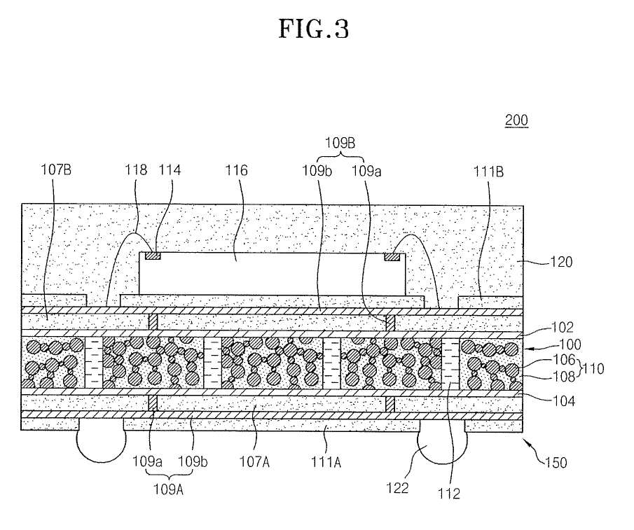

FIG. 3 is a sectional view illustrating a semiconductor package having the above-described printed circuit board in accordance with a third embodiment of the present invention.

Referring now to FIG. 3, a semiconductor package 200 in accordance with a third embodiment of the present invention includes a printed circuit board 150, a semiconductor chip 116 which is attached to one surface of the printed circuit board 150, and connection members 118 which connect the printed circuit board 150 and the semiconductor chip 116 with each other.

The printed circuit board 150 includes a copper-clad laminate 100 with a capacitor, insulation layers 107A and 107B which are formed on the lower and upper surfaces of the copper-clad laminate 100 facing away from each other, and wiring lines 109A and 109B which are placed on the insulation layers 107a and 107B.

The copper-clad laminate 100 with a capacitor includes a first conductive layer 102 and a second conductive layer 104 which face away from each other, a film body 110 which is interposed between the first conductive layer 102 and the second conductive layer 104, and thickness uniformity improving members 112 which are inserted in the film body 110.

The first conductive layer 102 and the second conductive layer 104 are formed of any one of, for example, Cu, Al, Ni, Fe, Au, Ag and admixtures thereof. The film body 110 includes a plurality of dielectric elements 106 and a binder 108 which captures the plurality of dielectric elements 106. The dielectric elements 106 can contain those selected from the group consisting of silica, barium titanate (BT), strontium titanate (ST), barium strontium titanate (BST), titanate (TiO₃), lead zirconium titanate (PZT), lead lanthanum titanate (PLT), lead lanthanum zirconate titanate (PLZT) bismuth titanate (BIT), potassium tantalite (KTA), lead scandium tantalite (PST), lead niobate (PN), lead zinc niobate (PZN), potassium niobate (KN), lead magnesium niobate (PMNO), strontium bismuth tantalate (SBT) and strontium bismuth tantalate niobate (SBTN), and combinations thereof. The dielectric elements 106 preferably contain any one of BaTiO₃, SrTiO₃ and inorganic silica filler, and the binder 108 contains epoxy resin. The dielectric elements 106 can be formed of any substance so long as the substance has a dielectric constant of 3˜1000. The thickness uniformity improving members 112 are inserted in the film body 110 in a manner so that one ends thereof contact the first conductive layer 102 and the other ends thereof facing away from the one ends contact the second conductive layer 104, and function to uniformly maintain the thickness of the film body 110. The thickness uniformity improving members 112 are formed of an insulation substance such as polypropylene, polyethylene, epoxy and nylon. The thickness uniformity improving members 112 have the shape of a column such as a circular column and a polygonal column or a ball. For example, the thickness uniformity improving members 112 are inserted in the film body 110 in such a way as to have the shape of a column which has a diameter and a thickness of about 2 μm and about 10 μm, respectively, and to be separated from one another by an interval of about 50 mm.

The insulation layers 107A and 107B are respectively formed on the lower and upper surfaces of the copper-clad laminate 100 which face away from each other. These insulation layers 107A and 107B can be formed to have a single-layered or multi-layered structure depending upon the desired thickness of the printed circuit board 150. The wiring lines 109A and 109B are placed on the insulation layers 107A and 107B and are electrically connected with the second conductive layer 104 and the first conductive layer 102, respectively. These wiring lines 109A and 109B include via wiring lines 109a which are formed in the insulation layers 107A and 107B and circuit wiring lines 109b which are formed on the insulation layers 107A and 107B.

The wiring lines 109A and 109B can be formed on both the upper and lower surfaces of the insulation layers 107A and 107B or selectively on either one of the upper and lower surfaces of the insulation layers 107A and 107B, depending upon the type of a package and the design of the printed circuit board 150. The printed circuit board 150 further includes solder resists 111A and 111B which are formed on the insulation layers 107A and 107B including the wiring lines 109A and 109B in such a way as to expose portions of the wiring lines 109A and 109B.

The semiconductor chip 116 is placed on one surface of the printed circuit board 150. The semiconductor chip 116 is attached to the one surface of the printed circuit board 150, for example, in a face-up type. Accordingly, the semiconductor chip 116 has bonding pads 114 placed on the upper surface adjacent to the edges thereof.

The connection members 118 are formed in such a way as to electrically connect the bonding pads 114 of the semiconductor chip 116 and the portions of the wiring lines 109B exposed through the solder resist 111B. The connection members 118 comprise, for example, metal wires. The exposed portions of the wiring lines 109B to which the connection members 118 are connected can be formed as bond fingers.

The semiconductor package 200 in accordance with the third embodiment of the present invention further includes an encapsulant 120 which is formed to cover the one surface of the printed circuit board 150 including the semiconductor chip 116 and the connection members 118 so as to protect the semiconductor chip 116 from external stresses. The encapsulant 120 comprises, for example, EMC (epoxy molding compound).

Also, the semiconductor package 200 in accordance with the third embodiment of the present invention further includes external connection terminals 122 which are attached to the portions of the wiring lines 109A exposed on the lower surface of the printed circuit board 150. The external connection terminals 122 comprise, for example, solder balls. The exposed portions of the wiring lines 109A to which the external connection terminals 122 are connected can be formed as ball lands.

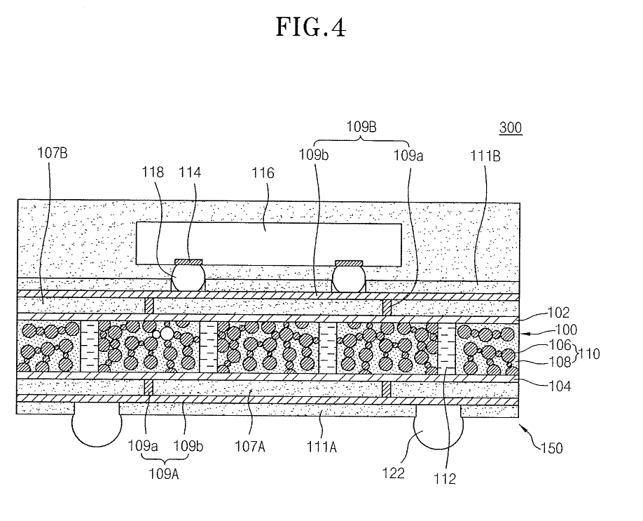

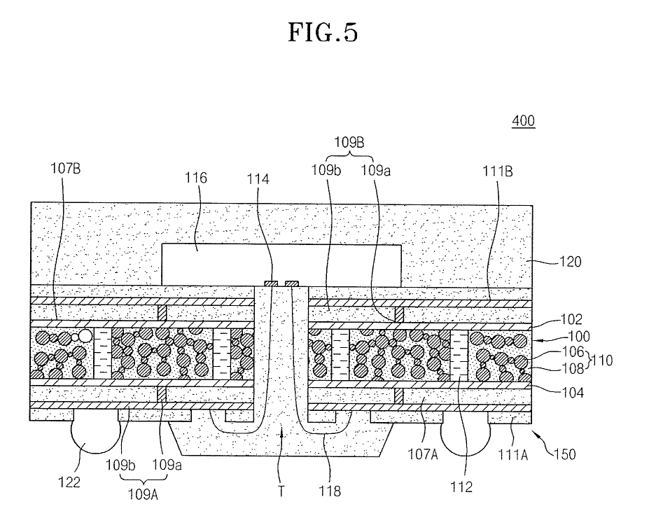

FIGS. 4 and 5 are sectional views illustrating semiconductor packages in accordance with fourth and fifth embodiments of the present invention.

Referring to FIGS. 4 and 5, semiconductor packages 300 and 400 in accordance with fourth and fifth embodiments of the present invention each includes a copper-clad laminate 100 with a capacitor and a printed circuit board 150 constituted using the copper-clad laminate 100 and has a construction similar to the third embodiment.

In the semiconductor packages 300 and 400 in accordance with the fourth and fifth embodiments of the present invention, a semiconductor chip 116 is attached to one surface of the printed circuit board 150 in a face-down type, and is constructed in a flip chip type in which bumps 118 are used as connection members or a BGA (ball grid array) type in which a cavity T is defined through the center portion of the printed circuit board 150 and connection members 118 are installed to pass through the cavity T.

The other component elements are the same as those described in the third embodiment of the present invention, and therefore, the detailed description thereof will be omitted herein.

As is apparent from the above description, in the present invention, since a film body, that is, a capacitor film is formed in a printed circuit board, not only the capacitor film can act as a substitute for a conventional core layer, but also the overall thickness of the printed circuit board can be decreased compared to the conventional art even though a capacitor is applied to a printed circuit board as the capacitor film.

Therefore, in the present invention, even without requiring various additional processes for directly integrating a passive device in a printed circuit board, a passive device such as a capacitor can be easily integrated in a printed circuit board, and thus, a process for forming a printed circuit board can be simplified.

Also, in the present invention, because the printed circuit board is constituted by inserting a plurality of thickness uniformity improving members in the capacitor film, the deformation of the capacitor film by external pressure can be prevented, and the thickness non-uniformity of the capacitor film can be compensated for. According to this fact, it is possible to prevent capacitance from becoming non-uniform in the printed circuit board. Therefore, it is possible to prevent the capacitance of the entire capacitor from decreasing.

In addition, in the present invention, due to the fact that it is possible to prevent the capacitance of the entire capacitor from decreasing, an adverse influence on the high speed operation of a product can be avoided. Moreover, since electrodes can be prevented from being disconnected while the thickness of a film is decreased, it is possible to prevent a semiconductor package from being sorted to be defective.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A copper-clad laminate with a capacitor, comprising:
a first and second conductive layers opposing each other;
a film body interposed between the first and the second conductive layers; and
thickness uniformity improving members between the first and second conductive layer and inserted in the film body, the thickness uniformity improving members having ends which are connected to the first conductive layer and having opposing ends connected to the second conductive layer such that the thickness uniformity improving members provide a substantial uniform thickness of the film body between the first and second conductive layers.

2. The copper-clad laminate according to claim 1, wherein the first and second conductive layers are formed of any one of Cu, Al, Ni, Fe, Au, Ag and admixtures thereof.

3. The copper-clad laminate according to claim 1, wherein the film body comprises a plurality of dielectric elements and a binder which captures the dielectric elements.

4. The copper-clad laminate according to claim 3, wherein the dielectric elements have a dielectric constant of about 3˜1000.

5. The copper-clad laminate according to claim 3, wherein the dielectric elements contain any one of those selected from the group consisting of silica, barium titanate (BT), strontium titanate (ST), barium strontium titanate (BST), titanate (TiO₃), lead zirconium titanate (PZT), lead lanthanum titanate (PLT), lead lanthanum zirconate titanate (PLZT), bismuth titanate (BIT), potassium tantalite (KTA), lead scandium tantalite (PST), lead niobate (PN), lead zinc niobate (PZN), potassium niobate (KN), lead magnesium niobate (PMNO), strontium bismuth tantalate (SBT) and strontium bismuth tantalate niobate (SBTN), and admixtures thereof.

6. The copper-clad laminate according to claim 3, wherein the binder contains epoxy resin.

7. The copper-clad laminate according to claim 1, wherein the thickness uniformity improving members are formed of an insulation substance.

8. The copper-clad laminate according to claim 7, wherein the insulation substance comprises any one of polypropylene, polyethylene, epoxy, nylon and admixtures thereof.

9. The copper-clad laminate according to claim 1, wherein the thickness uniformity improving members are formed in the shape of a column or a ball.

10. The copper-clad laminate according to claim 9, wherein the column comprises a cylindrical column or a polygonal column.

11. The copper-clad laminate according to claim 10, wherein the cylindrical column has a diameter of about 1.5˜2.5 μm and a height of about 9˜11 μm.

12. The copper-clad laminate according to claim 9, wherein the thickness uniformity improving members are inserted in the film body at an interval of about 48˜52 mm.

13. A printed circuit board comprising:
a copper-clad laminate with a capacitor, including
a first and second conductive layers opposing each other,
a film body interposed between the first and the second conductive layer, and
thickness uniformity improving members interposed between the first and second conductive layer and inserted within the film body, the thickness uniformity improving members having ends connected to the first conductive layer and the opposing ends connected to the second conductive layer;
insulation layers formed on the first and second conductive layers, respectively; and
wiring lines formed on the insulation layers and connected to the first and second conductive layers.

14. The printed circuit board according to claim 13, wherein the insulation layers are formed to have a single-layered or multi-layered structure.

15. The printed circuit board according to claim 13, wherein the wiring lines are formed in at least one of upper or lower surfaces of the insulation layers.

16. The printed circuit board according to claim 13, further comprising:
solder resists formed on the insulation layers and formed on the wiring lines in such a way as to expose portions of the wiring lines.

17. A semiconductor package comprising:
a printed circuit board including
a copper-clad laminate with a capacitor, the capacitor comprising
a first and a second conductive layer opposing each other,
a film body interposed between the first and the second conductive layer, and
thickness uniformity improving members interposed between the first and second conductive layers and inserted within the film body, the thickness uniformity improving members having one ends connected to the first conductive layer and having opposing ends connected to the second conductive layer,
insulation layers on the first and the second conductive layer, and
wiring lines formed on the insulation layers and connected to the first and second conductive layers;
a semiconductor chip attached to the printed circuit board wherein the semiconductor chip has bonding pads; and
connection members electrically coupled to the bonding pads of the semiconductor chip and electrically coupled to the wiring lines.

18. The semiconductor package according to claim 17, further comprising:
an encapsulant covering the one surface of the printed circuit board that has the semiconductor chip and the connection members attached to the printed circuit board; and
external connection members attached to another surface of the printed circuit board.

19. The semiconductor package according to claim 18, wherein the semiconductor chip is placed face-up on the one surface of the printed circuit board.

20. The semiconductor package according to claim 18, wherein the semiconductor chip is placed face-down on the one surface of the printed circuit board, wherein the printed circuit board has a cavity.
